(19) United States
(12) Patent Application Publication
(10) Pub. No.: US 2017/0271603 A1
(43) Pub. Date: Sep. 21, 2017

(54) SEMICONDUCTOR MEMORY DEVICE

(71) Applicant: Kabushiki Kaisha Toshiba, Minato-ku (JP)

(72) Inventors: Shigeki HATTORI, Kawasaki (JP); Masaya TERAI, Kawasaki (JP); Hideyuki NISHIZAWA, Toshima (JP); Koji ASAKAWA, Kawasaki (JP)

(73) Assignee: Kabushiki Kaisha Toshiba, Minato-ku (JP)

(21) Appl. No.: 15/378,604

(22) Filed: Dec. 14, 2016

(30) Foreign Application Priority Data
Mar. 16, 2016 (JP) 2016-053109

(51) Int. Cl. H01L 51/05; G11C 16/04; H01L 27/11551; H01L 29/788; H01L 27/11524

(52) U.S. Cl. CPC H01L 51/0545; H01L 29/788; H01L 27/11524; H01L 27/11551; G11C 16/04; H01L 51/005

(57) ABSTRACT

A semiconductor memory device of an embodiment includes a semiconductor layer, a gate electrode, and a charge storing layer provided between the semiconductor layer and the gate electrode. The charge storing layer includes polyoxometalates that contain copper (Cu) and tungsten (W).

### CROSS-REFERENCE TO RELATED APPLICATION

This application is based upon and claims the benefit of priority from Japanese Patent Application No. 2016-053109, filed on Mar. 16, 2016, the entire contents of which are incorporated herein by reference.

### FIELD

Embodiments described herein relate generally to a semiconductor memory device.

### BACKGROUND

As a method of realizing low bit cost of a semiconductor memory device and enhancing memory performance, a method of scaling down a size of a memory cell has been widely accepted. However, scaling down the memory cell is getting technically difficult.

It has thus been proposed to use charge storing molecules for a charge storing layer. The charge storing molecule having a variety of molecular structures and substituent groups can be synthesized. For this reason, intended electrochemical properties can be imparted to the charge storing molecule. Further, a unit of the charge storing molecule is small. Hence the use of the charge storing molecule may enable the realization of scaling-down of the memory cell.

In a semiconductor memory device using the charge storing molecules for the charge storing layer, further improvement in charge retention properties is required.

### BRIEF DESCRIPTION OF THE DRAWINGS

FIG. 1 is a sectional view of a memory cell unit of a semiconductor memory device according to a first embodiment.

FIG. 2 is a circuit diagram of a memory cell array of the semiconductor memory device according to the first embodiment.

FIG. 3 is a diagram showing an example of a polyoxometalate contained in the charge storing layer according to the first embodiment.

FIG. 4 is an enlarged schematic view of a memory cell unit of the semiconductor memory device according to the first embodiment.

FIG. 5 is a sectional view of a memory cell unit of a semiconductor memory device according to a second embodiment.

FIG. 6 is a sectional view of a memory cell unit of a semiconductor memory device according to a third embodiment.

FIG. 7 is a three-dimensional conceptual view of a semiconductor memory device according to a fourth embodiment.

FIG. 8 is an X-Y sectional view of FIG. 7.

FIG. 9 is an X-Z sectional view of FIG. 7.

FIG. 10 is a sectional view of a semiconductor memory device according to Modified Example 1 of the fourth embodiment.

FIG. 11 is a sectional view of a semiconductor memory device according to Modified Example 2 of the fourth embodiment.

FIG. 12 is a diagram showing charge retention properties in Example and Comparative Example.

### DETAILED DESCRIPTION

A semiconductor memory device of an embodiment includes a semiconductor layer, a gate electrode, and a charge storing layer provided between the semiconductor layer and the gate electrode. The charge storing layer includes polyoxometalates that contain copper (Cu) and tungsten (W).

In the present specification, the same numeral is added to the same or similar members, and a repeated description may be omitted.

In the present specification, “upper” and “lower” are used for showing the relative positional relation of components and the like. In the present specification, “upper” and “lower” are conceptually not necessarily terms showing the relation with the gravity direction.

Hereinafter, embodiments will be described with reference to the drawings.

### First Embodiment

A semiconductor memory device of the present embodiment includes: a semiconductor layer; a control gate electrode (gate electrode); and a charge storing layer provided between the semiconductor layer and the control gate electrode and containing polyoxometalates (POMs) that contain copper (Cu) and tungsten (W).

The semiconductor memory device of the present embodiment further includes a tunnel insulating layer provided between the semiconductor layer and the charge storing layer (first insulating layer) and the organic single molecular layer, and a block insulating layer (second insulating layer) provided between the charge storing layer and the gate electrode.

The semiconductor memory device of the present embodiment is provided with the charge storing layer between the tunnel insulating layer and the block insulating layer. The charge storing layer contains charge storing molecules. A molecular structure of the charge storing molecule contains an ion-pair compound. The ion-pair compound is formed of an ion-pair structure of a negatively charged polyoxometalate molecular unit and a positively charged counter ion (first cation).

By having the above configuration, the semiconductor memory device of the present embodiment realizes two stable states, a state where the polyoxometalate molecular unit holds an electron, and a state where the unit holds no electron. Hence electrons are stably held in the charge storing layer. This leads to improvement in charge retention properties (data retention properties) of a memory cell.

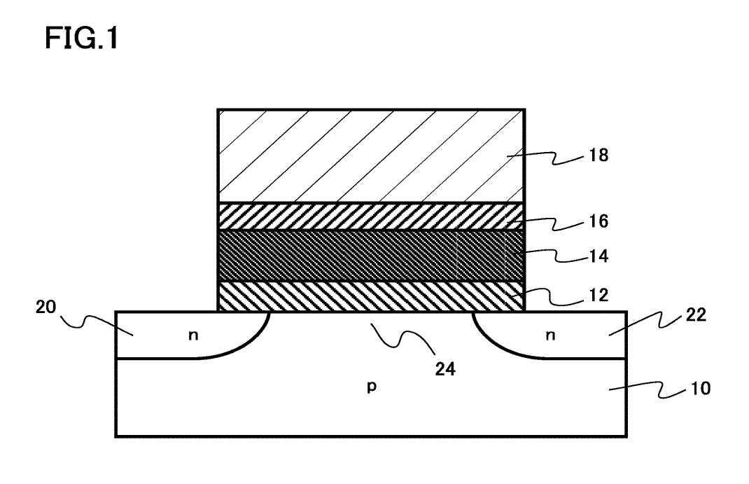

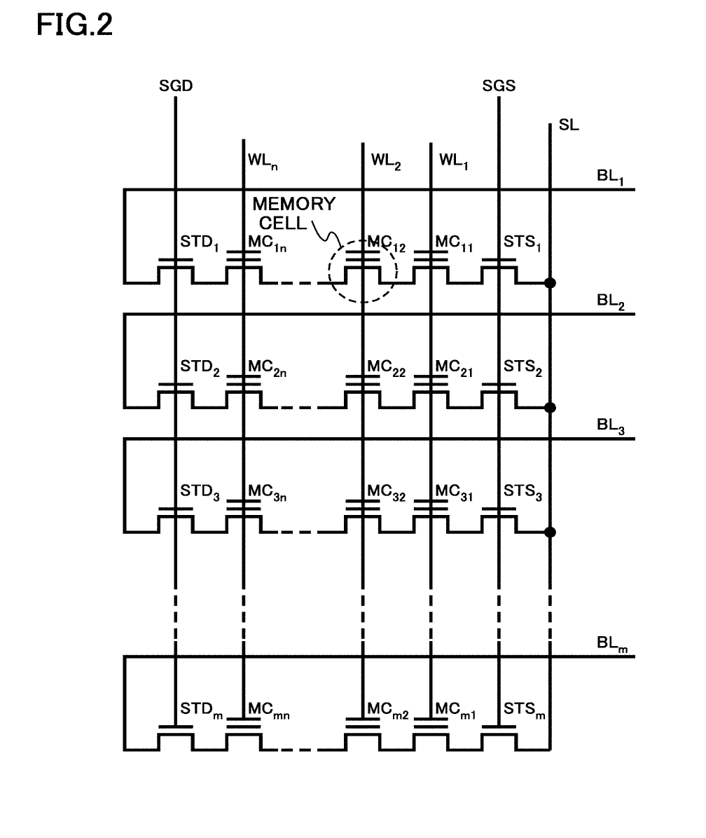

FIG. 1 is a sectional view of a memory cell unit of a semiconductor memory device according to the present embodiment. FIG. 2 is a circuit diagram of a memory cell array of the semiconductor memory device according to the present embodiment. The semiconductor memory device of the present embodiment is a NAND non-volatile semiconductor memory device.

As shown in FIG. 2, for example, the memory cell array is made up of memory cell transistors MC₁₁ to MC₁ₙ, MC₂₁ to MC₂ₙ, . . . , and MCₘ₁ to MCₘₙ, which are m×n (m and n are integers) transistors having a floating-gate structure. In the memory cell array, these memory cell transistors are arrayed in a column direction and in a row direction and a plurality of memory cell transistors are thereby disposed in a matrix form.

In the memory cell array, for example, the memory cell transistors MC₁₁ to MC₁ₙ and select gate transistors STS₁ and STD₁ are serially connected, to form a NAND string (memory string) that is a cell unit.

A drain region of the select gate transistor STS₁ for selecting the memory cell transistors MC₁₁ to MC₁ₙ is connected to a source region of the memory cell transistor MC₁₁ located at the end of the array of the serially connected group of the memory cell transistors MC₁₁ to MC₁ₙ. Further, a source region of the select gate transistor STD₁ for selecting the memory cell transistors MC₁₁ to MC₁ₙ is connected to a drain region of the memory cell transistor MC₁ₙ located at the end of the array of the serially connected group of the memory cell transistors MC₁₁ to MC₁ₙ.

Select gate transistors STS₂ to STSₘ, memory cell transistors MC₂₁ to MC₂ₙ, . . . , and MCₘ₁ to MCₘₙ, and select gate transistors STD₂ to STDₘ are also serially connected respectively, to constitute NAND strings.

A common source line SL is connected to the sources of the select gate transistors STS₁ to STSₘ. The memory cell transistors MC₁₁, MC₂₁, . . . , and MCₘ₁, the memory cell transistors MC₁₂, MC₂₂, . . . , and MCₘ₂, . . . and the memory cell transistors MC₁ₙ, MC₂ₙ, . . . , and MCₘₙ are respectively connected by word lines WL₁ to WLₙ configured to control operating voltages to be applied to the control gate electrodes.

Further, a common select gate line SGS for the select gate transistors STS₁ to STSₘ and a common select gate line SGD for the select gate transistors STD₁ to STDₘ are provided.

Note that a peripheral circuit, not shown and configured to control the memory cell array of FIG. 2, is formed on the periphery of the memory cell array.

FIG. 1 shows a cross section of a memory cell in the memory cell array shown in FIG. 2, e.g., a memory cell surrounded by a dotted line in FIG. 2. In the present embodiment, a description will be given by taking as an example a case where a transistor of the memory cell is an n-type transistor having electrons as carriers.

The memory cell is formed, for example, on a p-type silicon semiconductor layer 10 containing p-type impurities. Then, a tunnel insulating layer (first insulating layer) 12 is provided on the semiconductor layer 10, a charge storing layer 14 is provided on the tunnel insulating layer 12, a block insulating layer (second insulating layer) 16 is provided on the charge storing layer 14, and a control gate electrode (gate electrode) 18 is provided on the block insulating layer 16.

A source region 20 and a drain region 22 are formed in the semiconductor layer 10 on both sides of the control gate electrode 18. A region below the control gate electrode 18 in the semiconductor layer 10 is a channel region 24. The channel region 24 is interposed between the source region 20 and the drain region 22.

The charge storing layer 14 has a function to actively store charges as memory cell information. The tunnel insulating layer 12 functions as an electron/hole transfer pathway between the channel region 24 in the semiconductor layer 10 and the charge storing layer 14 through a tunneling phenomenon at the time of performing writing or erasing on the memory cell. The tunnel insulating layer 12 has a function to suppress transfer of electrons and holes between the channel region 24 and the charge storing layer 14 due to a barrier height of the tunnel insulating layer 12 at the time of performing reading or waiting. The block insulating layer 16 is a so-called interelectrode insulating layer, and has a function to block flows of electrons and holes between the charge storing layer 14 and the control gate electrode 18.

To the semiconductor layer 10, silicon germanide, germanium, a compound semiconductor, or the like can also be applied other than silicon.

The tunnel insulating layer 12 is a silicon oxide (SiO₂) film, for example. A material for the tunnel insulating layer 12 is not restricted to exemplified silicon oxide, but another insulating layer made of aluminum oxide or the like can be applied as appropriate.

The thicker the tunnel insulating layer 12, the higher the insulation properties, and the more hardly the stored charge escapes. However, when the tunnel insulating layer 12 is excessively thick, the semiconductor memory device has a large layer thickness itself, which is not preferred. Hence the tunnel insulating layer 12 preferably has a thickness of 10 nm or smaller, and more preferably has a thickness of 5 nm or smaller. Note that the foregoing thicknesses are all physical film thicknesses.

The tunnel insulating layer 12 may be a stacked film. For example, it is possible to stack materials suitable for promoting chemical bonding of organic molecules constituting the charge storing layer 14 to the surface of the tunnel insulating layer. For example, a stacked film of a silicon oxide film and an aluminum oxide film is applicable.

The charge storing layer 14 contains charge storing molecules. The charge storing layer 14 is, for example, made up of a monomolecular layer of the charge storing molecules. The charge storing layer 14 is preferably a monomolecular layer from the viewpoints of scaling down the memory cell and stabilizing the properties. The charge storing layer 14 preferably has a thickness of 2 nm or smaller from the viewpoint of scaling down the memory cell.

The block insulating layer 16 is a metal oxide such as hafnium oxide (HfO₂). For the block insulating layer 16, other than hafnium oxide described above, a metal oxide such as aluminum oxide (Al₂O₃), silicon oxide, zirconium oxide, or titanium oxide is used.

The thicker the block insulating layer 16, the higher the insulation properties, and the more hardly the stored charge escapes. However, when the block insulating layer 16 is excessively thick, the semiconductor memory device has a large film thickness itself, which is not preferred. Hence the block insulating layer 16 preferably has a thickness of 10 nm or smaller, and more preferably has a thickness of 5 nm or smaller.

The block insulating layer 16 may be either a monolayer film or a stacked film. The block insulating layer 16 is, for example, a metal oxide film formed by atomic layer deposition (ALD).

The control gate electrode 18 is, for example, polycrystalline silicon imparted with conductivity by introducing impurities. For the control gate electrode 18, any conductive material can be used. For the control gate electrode 18, other than the polycrystalline silicon described above, amorphous silicon imparted with conductivity by introducing impurities, or the like, can be used. Further, for the control gate electrode 18, metal, an alloy, a metal semiconductor compound or the like may be used.

The source region 20 and the drain region 22 are formed, for example, of n-type diffusion layers containing n-type impurities.

Each of the charge storing molecules contained in the charge storing layer 14 includes an ion-pair compound having an ion-pair structure of a cation and an anion. The charge storing molecule has a polyoxometalate molecular unit as an anion. Further, the charge storing molecule has a counter ion, configured to cancel a charge of the polyoxometalate molecular unit and hold an electrically neutral state, as a cation (first cation).

The polyoxometalate of the present embodiment is a polyoxometalate containing copper (Cu) and tungsten (W).

The polyoxometalate of the present embodiment includes a chemical structure described by a formula (1), for example.

CuₓW_{y}O_{z} (1)

In the above formula (1), x, y, and z are positive numbers, x is not larger than 1, y is not smaller than 6 and not larger than 12, and z is not smaller than 12 and not larger than 40.

The polyoxometalate of the present embodiment includes a chemical structure described by a formula (2), for example.

In the above formula (2), x, y, and z are positive numbers.

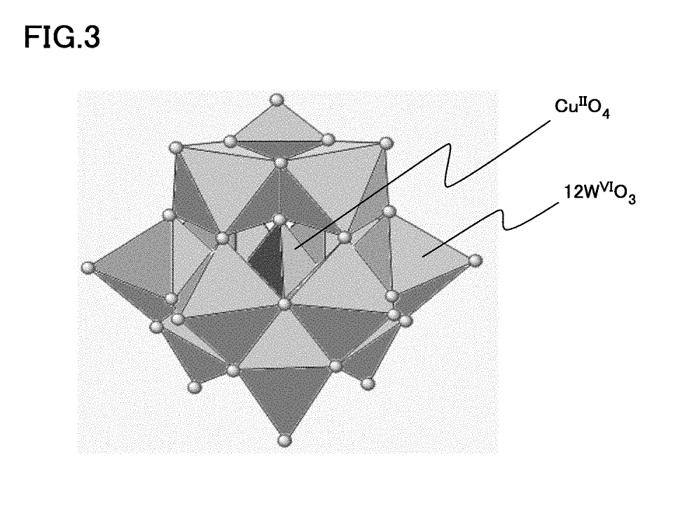

FIG. 3 is a diagram showing an example of the polyoxometalate contained in the charge storing layer according to the present embodiment. The polyoxometalate shown in FIG. 3 has a chemical composition of (CuW₁₂O₄₀)⁶⁻. The polyoxometalate shown in FIG. 3 has a structure where twelve regular octahedrons of tungsten oxide surround one regular tetrahedron of copper oxide. The polyoxometalate shown in FIG. 3 is a polyoxometalate having a structure so called the Keggin type. The Keggin-type polyoxometalate includes the chemical structure described by the above formula (1) or (2).

The charge storing molecule contains a linker unit. The charge storing molecule is chemically bonded to a region on the semiconductor layer side or a region on the control gate electrode side via the linker unit. For example, the molecule is chemically bonded to the tunnel insulating layer 12 or the block insulating layer 16 via the linker unit.

The linker unit is described by a formula (3). The linker unit includes at the end a chemically modifying group named linker. “LX” in the formula (3) is the linker.

LX-(LM)-LY (3)

In the above formula (3), LX is at least one chemically modifying group selected from a group consisting of an ether group, a silyl ether group, a dimethylsilyl ether group, a diethylsilyl ether group, a carboxy ester group, a sulfonyl ester group, a phosphonate ester group, an amide group, and a thioether group. LY is at least one second cation selected from a group consisting of an ammonium ion, a trimethylammonium ion, a triethylammonium ion, a tripropylammonium ion, a tributylammonium ion, a tripentylammonium ion, a trihexylammonium ion, a triheptylammonium ion, a trioctylammonium ion, a pyridinium ion, an anilinium ion, and an imidazolium ion. LM may or may not exist, and when existing, LM is at least one carbon chain structure selected from a group consisting of a methylene group, an ethylene group, a propylene group, a butylene group, a pentylene group, a hexylene group, a heptylene group, an octylene group, a nonylene group, a decylene group, an undecylene group, a dodecylene group, a tridecylene group, a tetradecylene group, a pentadecylene group, a hexadecylene group, a heptadecylene group, an octadecylene group, a nonadecylene group, an icosylene group, a phenylene group, a biphenylene group, and a terphenylene group.

Since the easiness for the linker to form a bond varies depending on a material for bonding, a chemical structure of the optimal linker varies depending on the material for bonding. For a semiconductor material or an insulating layer of a metal oxide or the like, for example, an ether group, a silyl ether group, a dimethylsilyl ether group, a diethylsilyl ether group, a carboxy ester group, a sulfonyl ester group, a phosphonate ester group, an amide group, and the like is preferred. From the viewpoints of easiness in organic synthesis and chemical reactivity with a metal oxide, the silyl ether group, the dimethylsilyl ether group, the diethylsilyl ether group, and the phosphonate ester group are preferred. Especially when the metal oxide is aluminum oxide, the phosphonate ester group is more preferred. Further, the linker unit may contain in its structure an alkyl group, a phenyl group or the like to serve as a spacer.

From the above viewpoint, the charge storing layer 14 of the present embodiment preferably includes a chemical structure described by a formula (4). The chemical structure of the formula (4) contains a linker unit containing a linker of the phosphonate ester group.

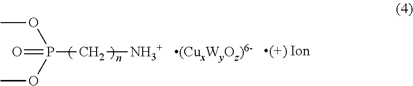

In the above formula (4), n is an integer not smaller than 1, x, y, and z are positive numbers, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

Further, the polyoxometalate molecular unit includes an inorganic structure formed of copper, tungsten, and oxygen as shown by the formula (4). The polyoxometalate having the inorganic structure is excellent in durability.

As shown in the formula (4), it is structured such that (+)Ion of the counter ion is selected from a positively charged ion, such as the tetramethylammonium ion, the tetraethylammonium ion, the tetrapropylammonium ion, the tetrabutylammonium ion, the rubidium ion, the cesium ion, and the barium ion.

Further, in the formula (4), the phosphonate ester group contained in the linker unit is the linker. The polyoxometalate and a positively charged quaternary ammonium ion contained in the linker unit in the formula (4) form an ion-pair structure, to fix the polyoxometalate and (+)Ion to the region on the semiconductor layer side or the region on the control gate electrode side.

Further, in the polyoxometalate in the formula (4), tungsten oxide sterically fixes a coordinate structure of a copper ion for receiving a charge. This leads to the occurrence of steric hindrance, making the coordinate structure of the copper ion hardly change before and after reception of a charge. Hence the polyoxometalate molecular unit, shown by the formula (4), hardly releases a charge received by writing. A charge being hardly released means longer memory time of the non-volatile semiconductor memory device. That is, it means improvement in charge retention properties (data retention properties).

In the charge storing molecule of the formula (4), the copper ion of the polyoxometalate molecular unit receives an electron, or releases it, to cause a change in molecular structure. By the copper ion receiving an electron or releasing it, the rearrangement of dipoles occurs. Hence two stable states exist; a state where the polyoxometalate molecular unit holds an electron, and a state where it holds no electron. Further, by the copper ion receiving an electron or releasing it, the counter ion is also rearranged in such a direction as to stabilize the two states. This further stabilizes the two states. It is thus possible to realize a non-volatile semiconductor memory device excellent in charge retention properties.

In particular, the polyoxometalate with the copper ion located at the center performs self-exchange at a slow rate. It is thus considered that the polyoxometalate hardly releases a charge as compared with the other inorganic complex compounds, to thereby improve the charge retention properties.

In the formula (4), n is the number of carbon chains of the alkyl group to serve as a spacer directly connected to the phosphonic acid linker. The longer the carbon chain, the more distant the copper ion for trapping a charge is from the semiconductor layer, and the more hardly the charge escapes into the semiconductor layer. Accordingly, the memory time of the non-volatile semiconductor memory device is long, which is considered to improve the data retention properties. However, an excessive long carbon chain makes it difficult to perform the organic synthesis, which is not preferred. Hence the number of carbon chains is preferably not smaller than 8 and not lager than 15. n is thus preferably not smaller than 8 and not larger than 15. Note that the number of carbon chains is more preferably 11.

The charge storing layer 14 of the present embodiment preferably includes a chemical structure described by a formula (5).

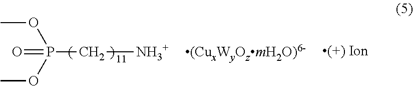

In the above formula (5), x, y, z, and m are positive numbers, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

In the formula (5), the number of carbon chains is 11. Further, the polyoxometalate in the formula (5) preferably has the Keggin structure so as to stabilize redox properties. Since a structural composition ratio changes in accordance with a synthesis method, x is not larger than 1, y is not smaller than 1 and not larger than 12, z is not smaller than 1 and not larger than 40, and m is not smaller than 1 and not larger than 10. Hence the charge storing layer 14 preferably includes a chemical structure described by a formula (6).

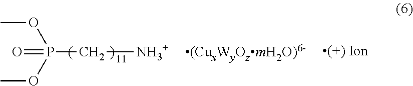

In the above formula (6), x, y, z, and m are positive numbers, x is not larger than 1, y is not smaller than 6 and not larger than 12, z is not smaller than 12 and not larger than 40, m is not smaller than 1 and not larger than 10, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

In the Keggin type, x, y, and z are preferably numbers of 1, 12, and 40, respectively. Hence the charge storing layer 14 preferably includes a chemical structure described by a formula (7).

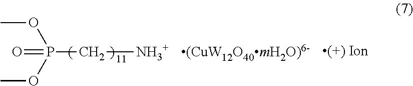

In the above formula (7), m is a number not smaller than 1 and not larger than 10, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

When m in the formula (7) is 10, the organic synthesis is easily performed. Hence the charge storing layer 14 preferably includes a chemical structure described by the formula (8).

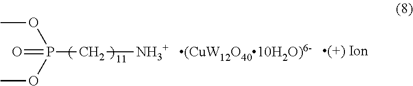

In the above formula (8), (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

When (+)Ion in the formula (8) is a counter ion with a larger ion radius, the counter is more easily rearranged, and its state before and after reception of a charge is electrostatically stabilized. From this viewpoint, (+)Ion is preferably an ion with a relatively large ion radius, such as the tetramethylammonium ion, the tetraethylammonium ion, the tetrapropylammonium ion, or the tetrabutylammonium ion. Hence the charge storing layer 14 preferably includes a chemical structure described by a formula (9).

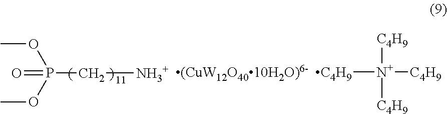

(+)Ion in the formula (9) is a tetrabutylammonium ion.

Note that a polyoxometalate having a structure other than the Keggin type is usable as the polyoxometalate. For example, an Anderson-type polyoxometalate is usable. The Anderson-type polyoxometalate is, for example, written by a formula (10).

(CuW₆O₂₄)¹⁰⁻ (10)

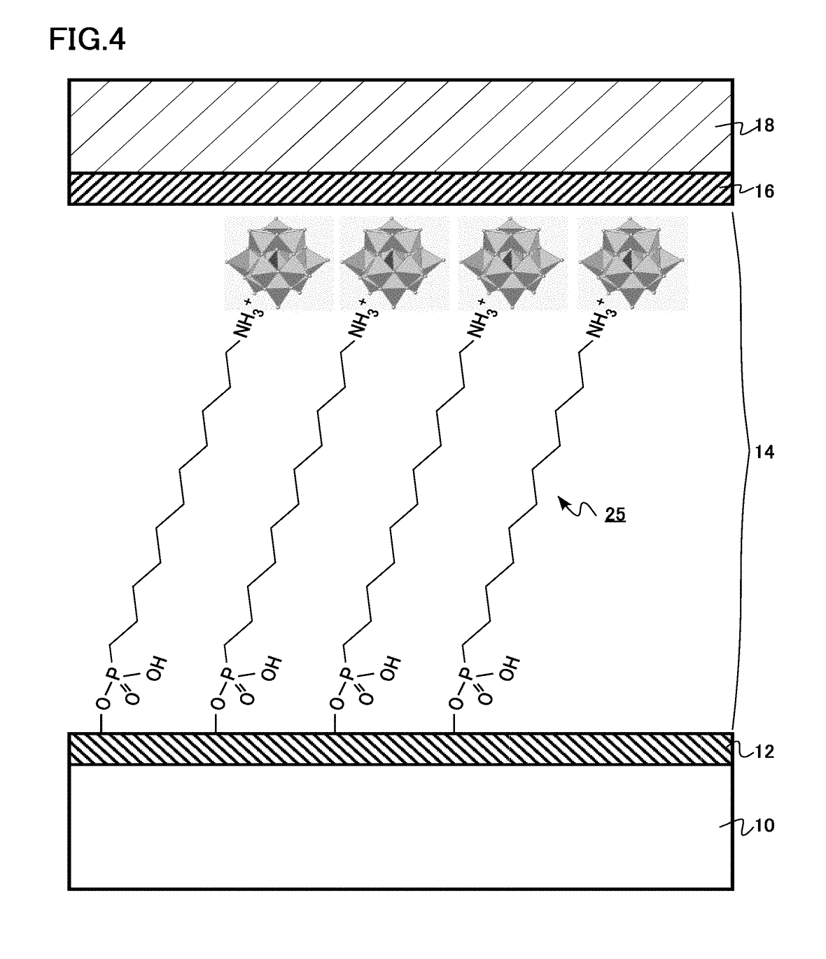

FIG. 4 is an enlarged schematic view of one example of a memory cell unit of the semiconductor memory device according to the present embodiment. This is a view showing a detail of a structure and adsorption pattern of each of organic molecules used for the charge storing layer 14.

The charge storing layer 14 is made up of charge storing molecules 25. The charge storing molecule 25 has a function to store a charge that serves as data of the memory cell.

The charge storing molecule 25 of the memory cell shown in FIG. 4 includes a chemical structure corresponding to the above formula (9). However, (+)Ion is not shown.

The tunnel insulating layer 12 is, for example, a stacked film of a silicon oxide film and an aluminum oxide film. One end of a phosphonate ester group as a linker of the charge storing molecule 25 is chemically bonded with the surface of the aluminum oxide film of the tunnel insulating layer 12, to constitute the charge storing layer 14. The charge storing layer 14 is a monomolecular layer of the charge storing molecules 25.

The charge storing molecule 25 in the charge storing layer 14 can be detected by the following analysis method, for example. That is, it can be detected using a mass spectroscope (MS), a secondary ionic mass spectrometer (SIMS), a nuclear magnetic resonator (NMR), an element analyzer, infrared reflection absorption spectroscopy (IR-RAS), an X-ray fluorescence instrument (XRF), X-ray photoelectron spectroscopy (XPS), an ultraviolet-visible spectrophotometer (UV-vis), a spectrofluoro-photometer (FL), or the like.

When an insulating layer of a metal oxide or the like is formed on the charge storing layer 14, the analysis is performed while the surface is ground with, for example, a sputter using argon ions or the like. Alternatively, the charge storing layer 14 is dissolved and peeled by a hydrofluoric acid aqueous solution or the like simultaneously with the insulating layer of the metal oxide or the like, and the solution is analyzed.

Further, in the method of grinding the surface by use of the above sputter or the like to perform the analysis, a heating treatment may be performed as the grinding method. In this case, a gas containing the ground material may be adsorbed to another material such as an activated carbon, and the other material such as the activated carbon with the gas adsorbed thereto may be analyzed and detected. Moreover, in the method of peeling the material by the above hydrofluoric acid aqueous solution or the like to analyze the solution, the solution containing the peeled material may be subjected to pressure reduction or a heating treatment for concentration, and the obtained solution may then be analyzed and detected.

Next, the operation of the memory cell of the present embodiment will be described.

At the time of performing writing operation on the memory cell of the present embodiment, a voltage is applied between the control gate electrode 18 and the semiconductor layer 10 such that the control gate electrode 18 reaches a relatively positive voltage, to store a negative charge in the charge storing layer 14. When the control gate electrode 18 reaches the relatively positive voltage, an inversion layer is formed in the channel region 24 to store electrons. The electrons transfer in the tunnel insulating layer 12, and are stored in the charge storing molecules 25 of the charge storing layer 14.

In this state, a threshold voltage of the transistor of the memory cell is high as compared with a state where the electrons are not stored. Namely, this is a state where the transistor is hardly turned on. This is a state where data “0” has been written.

At the time of performing data erasing operation, a voltage is applied between the control gate electrode 18 and the semiconductor layer 10 such that the control gate electrode 18 reaches a relatively negative voltage. Due to an electric field between the control gate electrode 18 and the semiconductor layer 10, the electrons stored in the charge storing layer 14 transfer in the tunnel insulating layer 12 and are drawn to the semiconductor layer 10.

In this state, a threshold voltage of the transistor of the memory cell is low as compared with the state of the data “0”. That is, this is a state where the transistor is easily turned on. This state is data “1”.

At the time of reading data, a voltage is applied between the source region 20 and the drain region 22. For example, in the state of data “0” where the electrons are stored, with the threshold voltage of the transistor being high, an inversion layer is not formed in the channel region 24, and a current does not flow between the source and the drain.

Meanwhile, in the erased state, namely in the state of the data “1” where the charges are not stored, with the threshold voltage of the transistor being low, an inversion layer is formed in the channel region 24, and a current flows between the source and the drain. As thus described, by detecting a current amount of the transistor, it is possible to read as to whether the data is the data “0” or the data “1”.

Note that at the time of performing data verifying operation to check whether or not writing has been sufficiently performed after performing the data writing operation, a similar operation to at the time of the reading operation is performed. A voltage is applied between the source region 20 and the drain region 22, and when an intended current does not flow, the data writing operation is performed again.

Next, a method for manufacturing the semiconductor memory device of the present embodiment will be described.

The method for manufacturing the semiconductor memory device of the present embodiment includes: forming the tunnel insulating layer 12 on the semiconductor layer 10; forming the charge storing layer 14 on the tunnel insulating layer 12; forming the block insulating layer 16 on the charge storing layer 14; and forming the control gate electrode 18 on the block insulating layer 16.

For example, the tunnel insulating layer 12 is formed on the semiconductor layer 10 of single crystal silicon. When the tunnel insulating layer 12 is silicon oxide, it can be formed, for example, by introducing a silicon substrate into a thermal oxidization furnace for forcible oxidation.

Further, the tunnel insulating layer 12 can also be formed using a film forming device for ALD, chemical vapor deposition (CVD), sputtering, or the like. In the case of film formation, it is preferable to anneal the insulating layer after formed by use of a rapid thermal annealing (RTA) device.

Subsequently, the charge storing layer 14 is formed on the tunnel insulating layer 12.

In the case of forming the charge storing layer 14, for example, the following methods are applicable.

First, the surface of the tunnel insulating layer 12 to be a foundation for forming the charge storing layer 14 is cleaned. For this cleaning, it is possible to employ, for example, cleaning by use of a mixed solution of sulfuric acid and hydrogen peroxide solution (a mixed ratio is 2:1, for example), or UV cleaning by irradiating the insulating layer surface with ultraviolet light.

Next, the chemical structure of the formula (4) is formed on the surface of the tunnel insulating layer. The chemical structure of the formula (4) is obtained by sequential soaking the surface into a solution of a molecule made up of a phosphonic acid linker and a quaternary ammonium ion, and a solution of a molecule made up of the polyoxometalate and (+)Ion.

First, the molecule made up of the phosphonic acid linker and the quaternary ammonium ion in the chemical structure of the formula (4) is prepared. A solution is prepared by dissolving into a dispersing agent the molecule made up of the phosphonic acid linker and the quaternary ammonium ion in a state prior to bonding to a ground as well as a state before ion-bonding between the polyoxometalate and (+)Ion. The surface of the cleaned tunnel insulating layer 12 is soaked into the prepared solution. Then, the phosphonic acid linker is reacted with the surface of the tunnel insulating layer 12.

The phosphonic acid linker in the state before bonding to the ground is phosphonic acid of a hydrogenated body. The state before ionic bonding between the polyoxometalate and (+)Ion is a state where the quaternary ammonium ion and another anion have formed an ion pair. As another anion is preferably an anion for facilitating the organic synthesis of the module made up of the phosphonic acid linker and the quaternary ammonium ion. Examples of another anion include a fluorine ion, a chlorine ion, a bromide ion, and an iodine ion.

As a dispersing agent, it is considered to use an agent with a high solubility of the module made up of the phosphonic acid linker and the quaternary ammonium ion. As the dispersing agent, such organic solvents are applicable as water, acetone, toluene, ethanol, methanol, hexane, cyclohexanone, benzene, chlorobenzene, xylene, acetonitrile, benzonitrile, tetrahydrofuran, dimethylsulfoxide, N,N-dimethylformamide, anisole, cyclohexanone, and methoxypropionic acid methyl. Further, a mixture of these solvents can also be used as the dispersing agent.

When a concentration of the molecule to be dissolved in the dispersing agent is excessively low, the reaction time becomes long. When the concentration is excessively high, the number of excess adsorbed molecules to be removed by rinsing operation increases. It is thus preferable to set an appropriate concentration. The set concentration is preferably about 0.1 mM to 100 mM, for example.

The time taken for soaking the surface of the tunnel insulating layer 12 in the molecule solution is preferably the extent of the time for sufficient reaction. Specifically, the time for soaking the surface in the molecule solution is preferably one minute or longer.

The surface is then soaked into the used dispersing agent, and rinsed using an ultrasonic cleaner. This operation is processing of rinsing an organic material physically adsorbed in excess. It is preferably performed twice or more by use of a new dispersing agent for each processing.

Subsequently, the surface is soaked into ethanol, and rinsed using the ultrasonic cleaner as in a similar manner to the above. Thereby, a monomolecular layer with the quaternary ammonium ion self-assembled on the surface is formed on the tunnel insulating layer 12.

The dispersing agent may then be removed by a nitride air gun, a spin coater or the like, followed by drying of the surface. Alternatively, the surface may not be dried, and may be continuously soaked into the polyoxometalate solution.

Next, the solution of the ion-pair compound made up of the polyoxometalate and (+)Ion shown in the chemical structure of the formula (4) is prepared. The surface of the foregoing monomolecular layer with the quaternary ammonium ion self-assembled on the surface is soaked into the solution obtained by dissolving into the dispersing agent the ion-pair compound made up of the polyoxometalate and (+)Ion. Then, the polyoxometalate and the quaternary ammonium ion are ionically bonded.

As the dispersing agent, it is considered to use a dispersing agent with a high solubility of the ion-pair compound made up of the polyoxometalate and (+)Ion. As the dispersing agent, such solvents are applicable as water, acetonitrile, benzonitrile, methanol, ethanol, N,N-dimethylformamide, dimethylsulfoxide, tetrahydrofuran, acetone, anisole, cyclohexanone, methoxypropionic acid methyl, and glycerin. Further, a mixture of these solvents can also be used as the dispersing agent.

When the concentration of the ion-pair compound to be dissolved in the dispersing agent is excessively low, the reaction time becomes long. When the concentration is excessively high, the number of excess adsorbed matters to be removed by rinsing operation increases. It is thus preferable to set an appropriate concentration. The set concentration is preferably about 0.1 mM to 100 mM, for example.

The time taken for soaking the surface of the quaternary ammonium ion in the ion-pair compound solution is preferably the extent of the time for sufficient reaction. Specifically the time for soaking the surface in the ion-pair compound solution is preferably one minute or longer.

The surface is then soaked into the used dispersing agent, and rinsed using the ultrasonic cleaner. This operation is processing of rinsing an organic material physically adsorbed in excess. It is preferably performed twice or more by use of a new dispersing agent for each processing.

The dispersing agent is then removed by the nitride air gun, the spin coater or the like, followed by drying, to obtain the charge storing layer 14 including the chemical structure of the formula (4) on the tunnel insulating layer 12.

Then, for example, a hafnium oxide film is deposited on the charge storing layer 14, to form the block insulating layer 16.

The block insulating layer 16 can be formed using a film forming device for ALD, CVD, sputtering, or the like. As the film forming device, it is preferable to use a film forming device that causes small damage on the charge storing layer 14 containing the organic molecules so that the charge storing layer 14 is not decomposed. For example, it is preferable to use a thermal ALD device. When the insulating layer after formed is annealed using the RTA device, an atomic density in the layer increases, which is preferable.

The, for example, an impurity-doped polycrystalline silicon film is formed by CVD, to form the control gate electrode 18. The stacked films are then patterned, thereby to form a gate electrode structure.

Subsequently, for example, n-type impurities as ions are implanted using the control gate electrode 18 as a mask, to form the source region 20 and the drain region. In such a manner, it is possible to manufacture the semiconductor memory device shown in FIG. 1.

As above, according to the present embodiment, by use of the charge storing molecule, which contains the polyoxometalate containing copper (Cu) and tungsten (W), for the charge storing layer 14, it is possible to provide a semiconductor memory device that realizes excellent charge retention properties.

### Second Embodiment

A semiconductor memory device of the present embodiment differs from the first embodiment in that the tunnel insulating layer is not provided and the charge storing layer has the function of the tunnel insulating layer. Hereinafter, descriptions in the present embodiment which overlap with those in the first embodiment will be omitted.

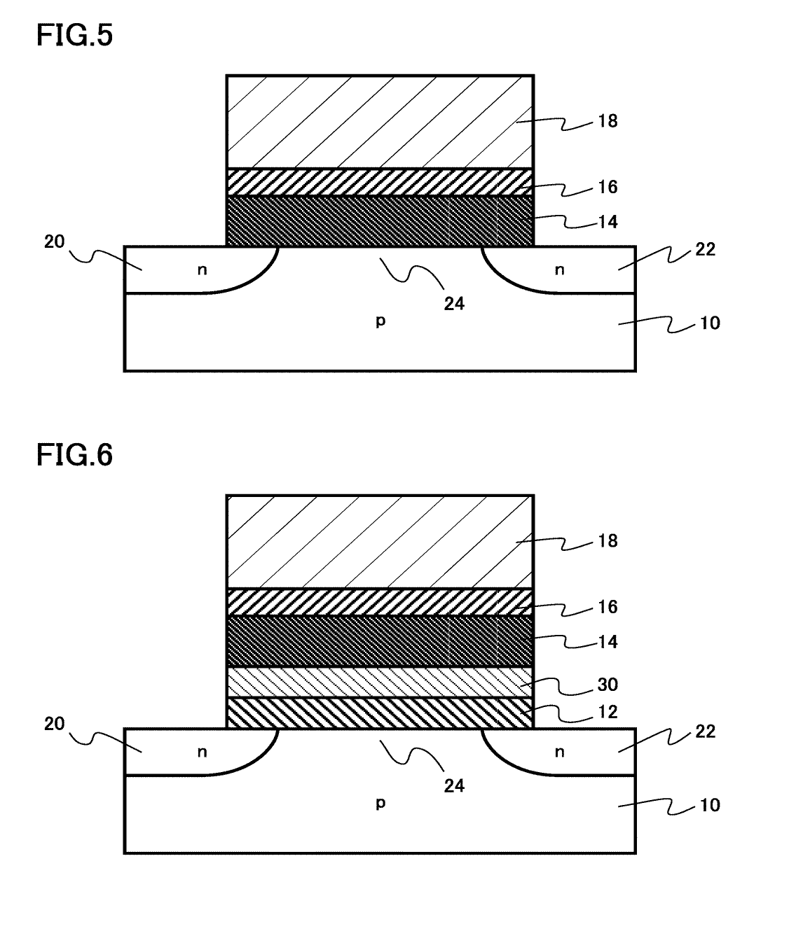

FIG. 5 is a sectional view of a memory cell unit of the semiconductor memory device according to the present embodiment.

The memory cell is formed, for example, on the n-type silicon semiconductor layer 10 containing n-type impurities. The memory cell includes the charge storing layer 14 on the semiconductor layer 10, the block insulating layer 16 on the charge storing layer 14, and the control gate electrode 18 on the block insulating layer 16. A source region 20 and a drain region 22 are formed in the semiconductor layer 10 on both sides of the control gate electrode 18. A region below the control gate electrode 18 in the semiconductor layer 10 is a channel region 24. The channel region 24 is interposed between the source region 20 and the drain region 22.

In the present embodiment, the charge storing molecule 25 in the charge storing layer 14 also has the function of the tunnel insulating layer. In the present embodiment, the charge storing molecule 25 is directly chemically bonded to the semiconductor layer 10.

Similarly to the first embodiment, the charge storing molecule 25 has a function to store charges that serve as data of the memory cell.

The linker unit of the charge storing molecule 25 includes a phosphonic acid linker and an alkyl chain, and a function to enhance insulation properties with the semiconductor layer 10 is expressed by the alkyl chain of the linker unit. For example in the above formula (4), the charge storing molecule 25 is an alkyl chain with the number (n) of carbon chains being 11 or larger in an alkyl chain portion.

The number of carbon chains of the alkyl chains is more preferably 11 or larger and 20 or smaller. When the number of carbon chains falls below the above range, the insulation resistance might deteriorate. Further, the self-assembled monomolecular layer might be hardly formed. When the number of carbon chains exceeds the above range, the organic synthesis might become difficult to perform. The number of carbon chains of the alkyl chains is preferably 11.

The method for manufacturing the semiconductor device of the present embodiment includes: forming the charge storing layer 14 that contains the charge storing molecules 25 having the chemical structure of the formula (4) on the semiconductor layer 10 by self-assembling; forming the block insulating layer 16 on the charge storing layer 14; and forming the control gate electrode 18 on the block insulating layer 16.

For example, the charge storing layer 14 is formed on the semiconductor layer 10 of single crystal silicon by self-assembling.

This is similar to the first embodiment except that the charge storing layer 14 is directly formed on the semiconductor layer 10.

According to the present embodiment, similarly to the first embodiment, it is possible to provide a semiconductor memory device that realizes excellent charge retention properties. Further, in place of the tunnel insulating layer of an inorganic material such as an oxide, the charge storing layer 14 realizes the function of the tunnel insulating layer. This enables the physical layer thickness of the memory cell structure. This leads to realization of a semiconductor memory device provided with a finer memory cell. Further, eliminating the need for formation of the tunnel insulating layer of the inorganic material can simplify the manufacturing process.

### Third Embodiment

A semiconductor memory device of the present embodiment is similar to the first embodiment except that a conductive layer is formed between the tunnel insulating layer and the charge storing layer. Hereinafter, descriptions in the present embodiment which overlap with those in the first embodiment will be omitted.

FIG. 6 is a sectional view of a memory cell unit of the semiconductor memory device according to the present embodiment.

The memory cell is formed, for example, on a p-type silicon semiconductor layer 10 containing p-type impurities. Then, the tunnel insulating layer 12 is provided on the semiconductor layer 10, a conductive layer 30 is provided on the tunnel insulating layer 12, the charge storing layer 14 is provided on the conductive layer 30, the block insulating layer 16 is provided on the charge storing layer 14, and the control gate electrode 18 is provided on the block insulating layer 16. A source region 20 and a drain region 22 are formed in the semiconductor layer 10 on both sides of the control gate electrode 18. A region below the control gate electrode 18 in the semiconductor layer 10 is a channel region 24. The channel region 24 is interposed between the source region 20 and the drain region 22.

The conductive layer 30 has a function to uniformly disperse a charge stored in the charge storing layer 14. Accordingly, a constant concentration distribution of the charge without variations is given inside the charge storing layer 14, to realize stable operation. Further, the conductive layer 30 has a function to improve the efficiency of reading and writing a charge stored in the charge storing layer 14.

The conductive layer 30 is, for example, a semiconductor film, a metal film, or a metal compound film. For example, it is possible to use polycrystalline silicon or amorphous silicon imparted with conductivity by introducing impurities.

In the case of the present embodiment, the charge storing molecule 25 is bonded onto the conductive layer 30 by self-assembling. At this time, when the conductive layer 30 is silicon, a chemically modifying group to serve as a linker of the charge storing molecule 25 is preferably a silyl ether group from the viewpoint of facilitating bonding.

The method for manufacturing the semiconductor memory device of the present embodiment includes: forming the tunnel insulating layer 12 on the semiconductor layer 10; forming the conductive layer 30 on the tunnel insulating layer 12; forming the charge storing layer 14 that contains the charge storing molecules 25 having the chemical structure of the formula (4) on the conductive layer 30; forming the block insulating layer 16 on the charge storing layer 14 by ALD, and forming the control gate electrode 18 on the block insulating layer 16.

The conductive layer 30 is formed on the tunnel insulating layer 12 for example by CVD, ALD, sputtering or the like. The charge storing layer 14 is then formed on the conductive layer 30.

This is similar to the first embodiment except that the tunnel insulating layer 12 is formed on the semiconductor layer 10 and the charge storing layer 14 is formed on the conductive layer 30.

According to the present embodiment, similarly to the first embodiment, it is possible to provide a semiconductor memory device that realizes excellent charge retention properties. This leads to realization of a semiconductor memory device that operates stably and has excellent reading and writing characteristics.

### Fourth Embodiment

A semiconductor memory device of the present embodiment includes: a stacked structure formed by alternately stacking insulating layers and gate electrodes; a semiconductor layer provided facing the gate electrode; and a charge storing layer provided between the semiconductor layer and at least one of the gate electrodes and containing polyoxometalates that contain copper (Cu) and tungsten (W).

The semiconductor memory device of the present embodiment differs from that of the first embodiment in that it is a device having a three-dimensional structure. Descriptions in the present embodiment which overlap with those in the first embodiment will be omitted.

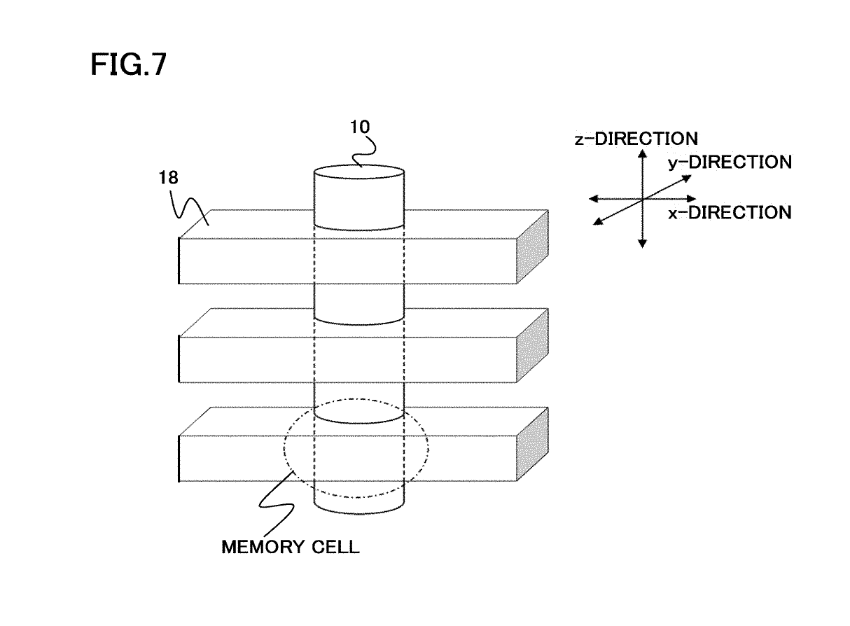

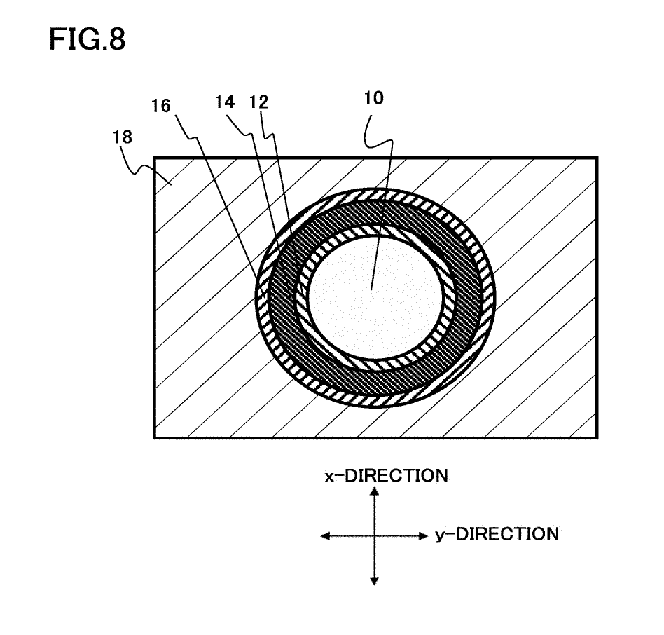

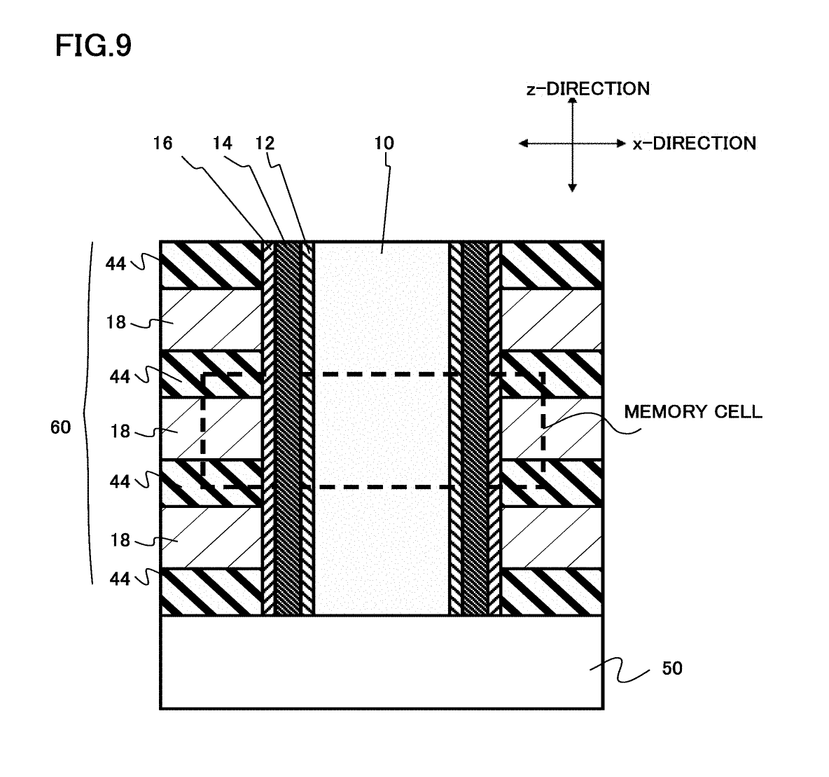

FIG. 7 is a three-dimensional conceptual view of the semiconductor memory device according to the present embodiment. FIG. 8 is an X-Y sectional view of FIG. 7. FIG. 9 is an X-Z sectional view of FIG. 7.

The semiconductor memory device of the present embodiment is provided, for example, with a stacked structure 60 where a plurality of insulating layers 44 and control gate electrodes (gate electrodes) 18 are alternately stacked on a silicon substrate 50.

Then, for example, a hole penetrating the stacked structure 60 from the top to the lowermost control gate electrode 18 is provided. The block insulating layer 16 is provided on the side surface of the hole, and the charge storing layer 14 is provided on the inner surface of the block insulating layer 16.

Further, the tunnel insulating layer 12 is provided on the inner surface of the charge storing layer 14. Moreover, the columnar semiconductor layer 10 is formed on the inner surface of the tunnel insulating layer 12. Note that the semiconductor layer 10 does not necessarily have the columnar shape, but may have a film shape, for example.

In other words, the semiconductor layer 10 is provided facing a plurality of control gate electrodes 18. Then, the tunnel insulating layer 12, the charge storing layer 14, and the block insulating layer 16 are provided between the semiconductor layer 10 and the control gate electrode 18.

In each of FIGS. 7 and 9, a region surrounded by a dashed line is one memory cell. The memory cell has a structure in which the tunnel insulating layer 12, the charge storing layer 14, and the block insulating layer 16 are formed between the semiconductor layer 10 and the control gate electrode 18.

The charge storing molecule 25 in the charge storing layer 14 contains the polyoxometalates containing copper (Cu) and tungsten (W). The charge storing molecule 25 is an organic molecule including the chemical structure described by the formula (4), for example.

The charge storing molecule 25 may be chemically bonded to either a region on the semiconductor layer 10 side or a region on the control gate electrode 18 side via the linker in the formula (4). For example, it is possible to form a configuration where the charge storing molecule 25 is chemically bonded to the tunnel insulating layer 12 via a linker. Further, for example, it can be configured such that the charge storing molecule 25 is chemically bonded to the block insulating layer 16 via a linker.

Note that the three-dimensional structure of the present embodiment can be manufactured by applying a known method for manufacturing a semiconductor memory device with a three-dimensional structure.

According to the present embodiment, similarly to the first embodiment, it is possible to provide a semiconductor memory device that realizes excellent charge retention properties. Further, according to the present embodiment, making the memory cell three-dimensional leads to an increase in integration degree of the memory cell, thereby enabling realization of a semiconductor memory device with a higher integration degree than those in the first to third embodiments.

### Modified Example 1

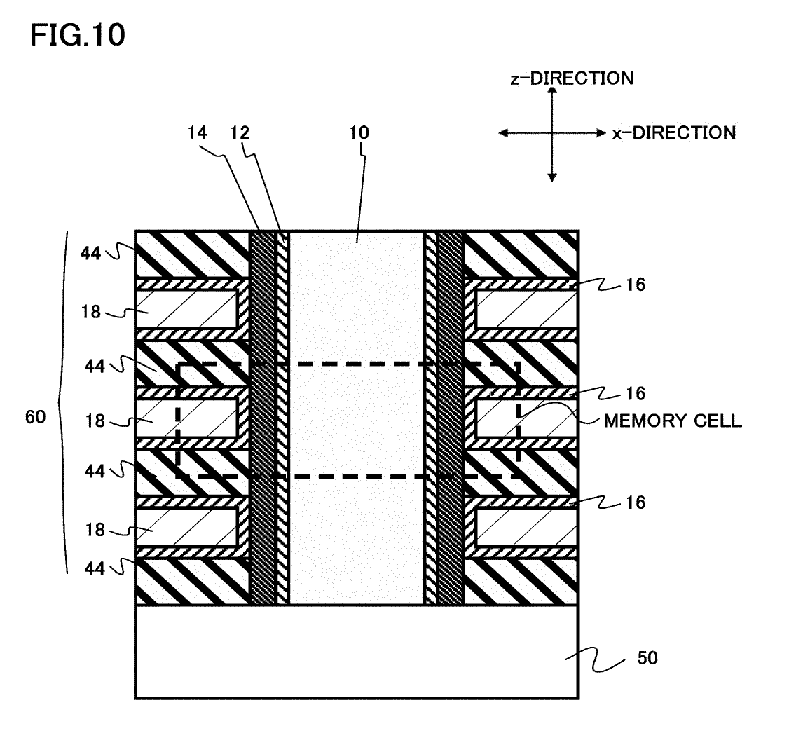

FIG. 10 is a sectional view of a semiconductor memory device according to Modified Example 1 of the present embodiment. It shows a cross section corresponding to the sectional view of FIG. 9. The block insulating layer 16 is provided along and between the control gate electrode 18 and the insulating layer 44. The block insulating layer 16 is divided for each memory cell disposed in a z-direction.

### Modified Example 2

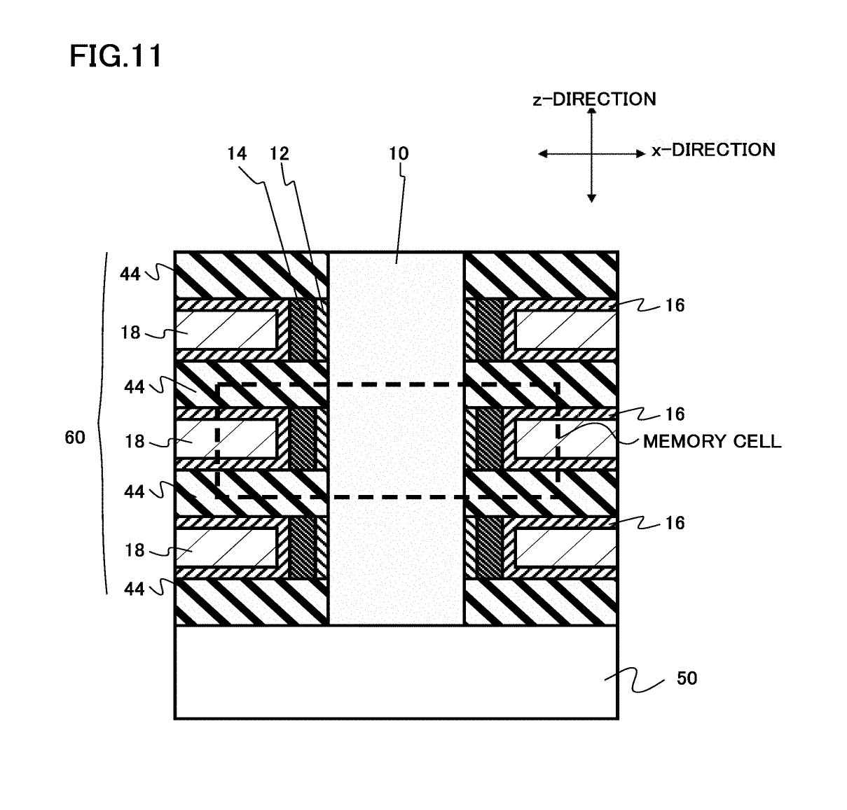

FIG. 11 is a sectional view of a semiconductor memory device according to Modified Example 2 of the present embodiment. It shows a cross section corresponding to the sectional view of FIG. 9. Similarly to Modified Example 1, the block insulating layer 16 is provided along and between the control gate electrode 18 and the insulating layer 44. The block insulating layer 16 is divided for each memory cell disposed in a z-direction. Further, the tunnel insulating layer 12 and the charge storing layer 14 are also divided for each memory cell disposed in the z-direction.

### Example

In the following, an example will be described.

### Example

A transistor element with four terminals was produced by the following method.

A p-type silicon substrate was patterned by a photoresist and phosphorus ions are implanted, to form an n-type region. Subsequently, a silicon oxide film was formed on a channel region in a thermal oxidization furnace. A film thickness of the silicon oxide film was about 5 nm as a result of measuring the film thickness.

A substrate formed with the silicon oxide film was introduced to an ALD device, and an aluminum oxide film was formed for just one cycle, to form a tunnel insulating layer made up of a stacked film of the silicon oxide film and the aluminum oxide film.

The substrate formed with the tunnel insulating layer was cleaned by irradiation of the surface of the formed aluminum oxide film by a UV cleaner for ten minutes. In Example, the cleaned substrate was soaked into a solution obtained by dissolving 11-aminoundecylphosphonic acid, hydrobromide into ethanol at a concentration of 1 mM, and left to stand during a whole day and night.

Then, the substrate was removed from the solution and transferred into pure ethanol, and then rinsed while being stimulated by the ultrasonic cleaner for one minute. Note that this rinsing operation by use of ethanol was performed three times in total as ethanol was replaced by a new one each time. Then, the substrate was dried using an air duster, to form a quaternary ammonium ion on the substrate.

Subsequently, the substrate is soaked into a solution obtained by dissolving an ion-pair compound, which is six tetrabutylammonium salts (6TBA⁺) of a polyoxometalate (Cu_{0.36}, W_{10.91}, O₄₀.10H₂O)⁶⁻, into acetonitrile at a concentration of 1 mM, and left to stand during a whole day and night.

Then, the substrate was removed from the solution and transferred into pure acetonitrile, and then rinsed while being stimulated by the ultrasonic cleaner for one minute. Note that this rinsing operation by use of acetonitrile was performed twice in total as acetonitrile was replaced by a new one. The substrate was transferred into pure ethanol, and then rinsed once while being stimulated by the ultrasonic cleaner for one minute. Then, the substrate was dried using the air duster, to fix an ion-pair compound of a polyoxometalate being (Cu_{0.36}, N_{10.91}, O₄₀.10H₂O)⁶⁻.6TBA⁺. A charge storing monomolecular layer is formed on the substrate.

Next, the substrate was introduced to a thermal ALD device, to form a block insulating layer of hafnium oxide on the charge storing monomolecular layer at 150° C. A film thickness of the block insulating layer of hafnium oxide was set to about 10 nm.

Subsequently, it was introduced to the RTA device, and annealed under an N₂ gas atmosphere mixed with 3% of H₂ at 300° C. for 30 minutes, and nickel with a thickness of about 100 nm was stacked on hafnium oxide by an electron beam (EB) deposition device. A deposited nickel film was patterned by a photoresist to be left only in a channel region, thereby forming a gate electrode.

Next, a source-drain unit linked to the channel region was patterned by a photoresist so as to be opened. It was then wet-etched by buffered hydrofluoric acid, and the silicon surface of the source-drain unit was exposed. Aluminum with a thickness of about 100 nm was deposited on the silicon surface, to form a source-drain electrode. Further, the rear surface of the substrate was wet-etched and cleaned by hydrofluoric acid, and aluminum with a thickness of about 200 nm was deposited, to form a substrate electrode, thereby producing a transistor element made up of four terminals of the gate, source, drain, and substrate.

### Comparative Example

A transistor element was produced in a similar manner to Example except that the charge storing monomolecular layer was not formed and a block layer of hafnium oxide was formed directly on a tunnel insulating layer.

A voltage of 9 V was written into the gate electrode of the transistor element in each of Example and Comparative Example by taking the time of 100 ms, and a threshold voltage shift (ΔVth) generated by writing was read. Then, the threshold voltage shift was traced with respect to the elapsed time.

Note that the reading was performed by constantly applying a source-drain voltage of 0.1 V to read a drain current obtained by applying a gate voltage of 0 V to 5 V. A voltage obtained upon flowing of a drain current of 1×10⁻⁷ A was taken as a threshold voltage.

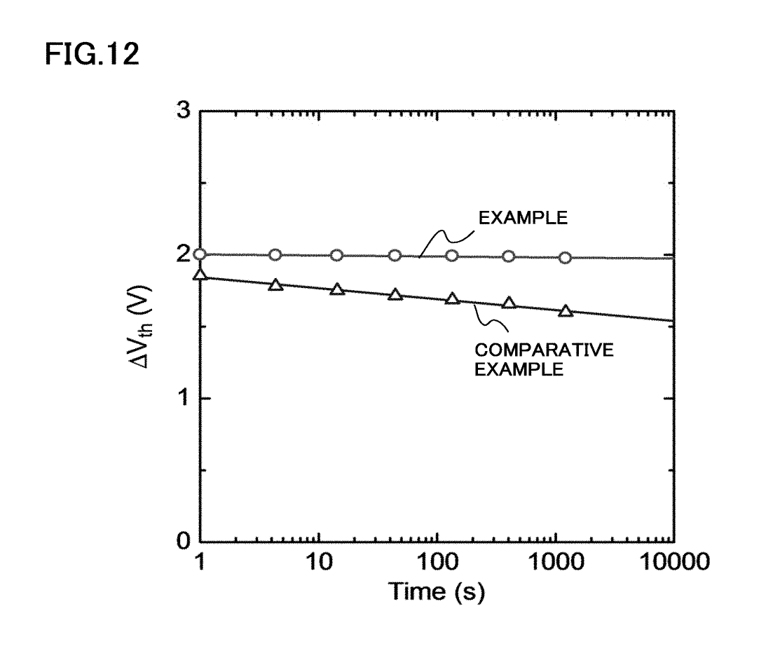

FIG. 12 is a diagram showing charge retention properties in Example and Comparative Example. It shows temporal changes in threshold voltage shift. Each of the temporal changes in threshold voltage shift obtained in FIG. 12 was linearly logarithmically approximated to attenuate 5% of an initial threshold voltage shift value. The calculated elapsed time was about 4.7×10⁶ years in Example, and about 16.3 seconds in Comparative Example. It was thus found that the charge storage time in Example is longer and more excellent than that in Comparative Example.

The above result revealed that the charge storage time of 10 years or longer can be obtained according to the semiconductor memory device of the present disclosure.

While certain embodiments have been described, these embodiments have been presented by way of example only, and are not intended to limit the scope of the inventions. Indeed, a semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a semiconductor layer;
a gate electrode; and
a charge storing layer provided between the semiconductor layer and the gate electrode, the charge storing layer including polyoxometalates containing copper (Cu) and tungsten (W).

2. The device according to claim 1, wherein each of the polyoxometalates includes a chemical structure described by a formula (1):
CuₓW_{y}O_{z} (1)
in the above formula (1), x, y, and z are positive numbers, x is not larger than 1, y is not smaller than 6 and not larger than 12, and z is not smaller than 12 and not larger than 40.

3. The device according to claim 1, wherein each of the polyoxometalates includes a chemical structure described by a formula (2):
(CuₓW_{y}O_{z})⁶⁻ (2)
in the above formula (2), x, y, and z are positive numbers.

4. The device according to claim 1, wherein the charge storing layer includes at least one first cation selected from a group consisting of a tetramethylammonium ion, a tetraethylammonium ion, a tetrapropylammonium ion, a tetrabutylammonium ion, a rubidium ion, a cesium ion, and a barium ion.

5. The device according to claim 1, wherein the charge storing layer includes a linker unit containing at least one chemically modifying group selected from a group consisting of an ether group, a silyl ether group, a dimethylsilyl ether group, a diethylsilyl ether group, a carboxy ester group, a sulfonyl ester group, a phosphonate ester group, an amide group, and a thioether group.

6. The device according to claim 1, wherein the charge storing layer includes a linker unit described by a formula (3):
LX-(LM)-LY (3)
in the above formula (3), LX is at least one chemically modifying group selected from a group consisting of an ether group, a silyl ether group, a dimethylsilyl ether group, a diethylsilyl ether group, a carboxy ester group, a sulfonyl ester group, a phosphonate ester group, an amide group, and a thioether group; LY is at least one second cation selected from a group consisting of an ammonium ion, a trimethylammonium ion, a triethylammonium ion, a tripropylammonium ion, a tributylammonium ion, a tripentylammonium ion, a trihexylammonium ion, a triheptylammonium ion, a trioctylammonium ion, a pyridinium ion, an anilinium ion, and an imidazolium ion; and LM may or may not exist, and when existing, LM is at least one carbon chain structure selected from a group consisting of a methylene group, an ethylene group, a propylene group, a butylene group, a pentylene group, a hexylene group, a heptylene group, an octylene group, a nonylene group, a decylene group, an undecylene group, a dodecylene group, a tridecylene group, a tetradecylene group, a pentadecylene group, a hexadecylene group, a heptadecylene group, an octadecylene group, a nonadecylene group, an icosylene group, a phenylene group, a biphenylene group, and a terphenylene group.

7. The device according to claim 6, wherein the LX in the linker unit is chemically bonded to a region on the semiconductor layer side or a region on the gate electrode side, and the LY is chemically bonded to the polyoxometalate.

8. The device according to claim 1, wherein the charge storing layer contains water (H₂O).

9. The device according to claim 1, wherein the charge storing layer includes a chemical structure described by a formula (4): 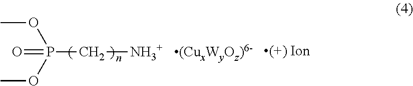
in the above formula (4), n is an integer not smaller than 1, x, y, and z are positive numbers, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

10. The device according to claim 1, wherein the charge storing layer includes a chemical structure described by a formula (5): 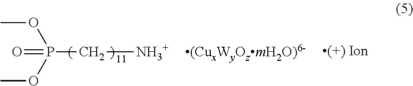
in the above formula (5), x, y, z, and m are positive numbers, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

11. The device according to claim 1, wherein the charge storing layer includes a chemical structure described by a formula (6): 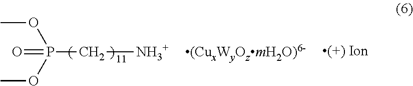
in the above formula (6), x, y, z, and m are positive numbers, x is not larger than 1, y is not smaller than 6 and not larger than 12, z is not smaller than 12 and not larger than 40, m is not smaller than 1 and not larger than 10, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

12. The device according to claim 1, wherein the charge storing layer includes a chemical structure described by a formula (7): 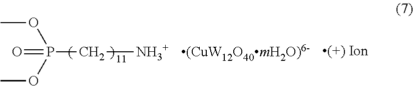
in the above formula (7), m is a number not smaller than 1 and not larger than 10, and (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

13. The device according to claim 1, wherein the charge storing layer includes a chemical structure described by a formula (8): 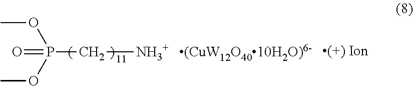
in the above formula (8), (+)Ion is at least one first cation selected from a group consisting of a tetramethylammonium ion, a tetraethylammonium ion, a tetrapropylammonium ion, a tetrabutylammonium ion, a rubidium ion, a cesium ion, and a barium ion.

14. The device according to claim 1, wherein the charge storing layer includes a chemical structure described by a formula (9):

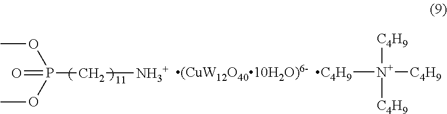

15. The device according to claim 1, wherein the charge storing layer is a monomolecular layer.

16. The device according to claim 1, further comprising
a first insulating layer provided between the semiconductor layer and the charge storing layer.

17. The device according to claim 1, further comprising
a second insulating layer provided between the charge storing layer and the gate electrode.

18. A semiconductor memory device, comprising:
a stacked structure formed by alternately stacking insulating layers and gate electrodes;
a semiconductor layer provided facing the gate electrode; and
a charge storing layer provided between the semiconductor layer and at least one of the gate electrodes, the charge storing layer including polyoxometalates containing copper (Cu) and tungsten (W).

19. The device according to claim 18, wherein each of the polyoxometalates includes a chemical structure described by a formula (1):
CuₓW_{y}O_{z} (1)
in the above formula (1), x, y, and z are positive numbers, x is not larger than 1, y is not smaller than 6 and not larger than 12, and z is not smaller than 12 and not larger than 40.

20. A semiconductor memory device, comprising:
a semiconductor layer;
a gate electrode; and
a charge storing layer provided between the semiconductor layer and the gate electrode, the charge storing layer containing copper (Cu), tungsten (W), and oxygen (O) and including a structure in which the tungsten and the oxygen surround the copper.
